(19) United States
(12) Patent Application Publication
(10) Pub. No.: US 2011/0019980 A1
(43) Pub. Date: Jan. 27, 2011

(54) Integrated Boiler Component Wiring Assembly and Method

(76) Inventor: James T. Harper, Eagle, CO (US)

Correspondence Address: JOHN R LEY, LLC, 5299 DTC BLVD, SUITE 340, GREENWOOD VILLAGE, CO, 80111, US

(21) Appl. No.: 12/510,091

(22) Filed: Jul. 27, 2009

(51) Int. Cl. H05B 3/60; H05K 5/02

(52) U.S. Cl. 392/312; 392/320; 174/549

(57) ABSTRACT

An integrated wiring assembly electrically connects components of a multi-zone boiler heating system. The integrated wiring assembly includes a plurality of connection terminals which are commonly connected to facilitate connecting thermostats and zone valves for each zone, end switches of each zone valve to a start switch of the boiler, and a transformer to supply electrical power to the components, in such a way that the complexity of the electrical connections is simplified.

This invention relates to electrically connecting together various components of a boiler heating system. More particularly, the present invention relates to a new and improved integrated wiring assembly and method which greatly facilitates electrically connecting the components of the boiler heating system and which aids in more quickly diagnosing problems associated with the components of the boiler heating system.

### BACKGROUND OF THE INVENTION

Boiler heating systems are widely used to heat residential and commercial buildings. A typical boiler heating system includes a boiler, pipes, radiators and water or similar heat transfer fluid. The boiler generates heat from a heat source, such as a resistive heating element or a combustion chamber in which fuel is burned. The heat is transferred to the water, and the heated water is then pumped through supply pipes to radiators located within the interior of a building. Heat from the heated water flowing through the radiators is transferred to the cooler air. The relatively cooler water from the radiator is then returned to the boiler through return pipes to be heated and circulated again through the radiator.

Particular areas of the building, referred to as zones, are heated independently of other zones in the building. Each zone is heated by at least one radiator. A zone valve controls the flow of heated water from the boiler to each radiator in that zone. A thermostat is located in each zone, and the thermostat controls the zone valve for that zone. In this way, each zone valve is controlled independently of the others to allow independent control of the heat within each different zone in the building.

The thermostat and the zone valve for each zone are connected in series with a transformer which provides electrical power to operate those components. The thermostat functions as a temperature responsive switch which closes when the measured temperature of the air falls below a selected temperature and which opens when the temperature is at or greater than the selected temperature. When the thermostat switch closes, electrical power is delivered to the zone valve, causing the zone valve to open, and the open zone valve conducts heated water through the supply pipes to the radiator within the zone. The flow of heated water through the radiator eventually heats up the air within the zone until the temperature of the air within the zone reaches or exceeds the selected temperature. At that point the switch of the thermostat opens, causing the zone valve to close. The closed zone valve terminates the flow of heated water through the radiator. Thus, the thermostat is closed and the zone valve for a particular zone is opened when the temperature within that zone is less than the selected temperature, and the thermostat is open and the zone valve for the particular zone is closed when the temperature within the zone is at or greater than the selected temperature. In this manner, the temperature in each particular zone is regulated and maintained at approximately the selected temperature.

The boiler may include a hot water storage tank in which a supply of hot water is always maintained. The boiler may also heat the hot water for delivery to the radiators whenever hot water is requested by a thermostat. The boiler includes a start switch which activates both the heat source and an internal pump to circulate the heated water. In a situation where the boiler includes a hot water storage tank, the start switch activates the internal pump to circulate the heated water through the zone valves to the radiators, and a separate thermostatic switch associated with the hot water storage tank may control the heat source of the boiler. In the situation where the boiler heats the hot water when the thermostat requests heat, the heat source of the boiler and the internal pump are activated simultaneously by the start switch. An end switch is connected to each zone valve, and the end switch closes when the zone valve is opened. The boiler start switch is connected in parallel with all of the end switches of the all of the zone valves. Connected in this manner, the start switch is closed and the internal pump (and possibly the heat source) are operated when any one of the zone valves is opened by the thermostat.

Properly connecting the end switches, the boiler start switch, the thermostats in each zone and the zone valves is typically one of the most difficult wiring tasks for a technician to learn. Many hours are typically expended in training technicians to properly wire the different components of the boiler heating system. One of the factors that contributes to the difficulty in learning to correctly connect the components of the boiler heating system is a lack of organization of the wires connecting the components. Usually, these wires are not labeled and often must be traced to the boiler start switch, the transformer, the thermostats and the zone valves, in order to determine which wires are connected to what components. Even experienced technicians can spend a significant amount of time determining the wiring configuration. The time spent trying to determine which roles the connecting wires in a boiler heating system play adds extra cost to service calls. The cost to install a typical boiler heating system is also more expensive due to the lack of organization and clear identification of the electrical conductors which connect the boiler heating system components.

### SUMMARY OF THE INVENTION

The present invention pertains to an integrated boiler component wiring assembly which facilitates electrically connecting the components of a boiler heating system. The integrated wiring assembly reduces the amount of time required to electrically wire or connect the components of the boiler heating system. Diagnosing problems with the components of the boiler heating system is facilitated due to the organization of the wires and the ease with which electrical wires connected to the integrated wiring assembly can be identified. The costs of training technicians to wire the electrical connections of the boiler heating system components is also substantially reduced, due to the clarity and understanding of the electrical connections of the integrated wiring assembly. The costs of service calls involving malfunctioning components of the boiler heating system should also be reduced as a consequence of not having to trace the electrical conductors connecting the boiler components.

In accordance with these and other considerations, one aspect of the invention involves an integrated wiring assembly for connecting the components of a boiler heating system. The housing includes a elongated body, two opposite end connection sections and a plurality of intermediate zone connection sections between the end connection sections. Each end connection section includes a plurality of end connection terminals, and each zone connection section includes a plurality of zone connection terminals. Internal conductors connect the end connection terminals to the zone connection terminals, with each internal conductor connecting one end connection terminal with one zone connection terminal of each zone connection section. The zone valves and thermostats of one zone are connected to the zone connection terminals associated with each zone. The transformer and the boiler start switch are respectively connected to the end connection terminals to deliver electrical power to the components of each of the zones and to assure control of the boiler from each of the zones.

Another aspect of the invention involves a method of electrically connecting components of a boiler heating system using an integrated wiring assembly having four internal conductors. The method involves using the integrated wiring assembly to connect two leads of a transformer to a first two of the four internal conductors, connecting two leads of a boiler start switch to a second two of the four internal conductors, connecting a thermostat in series with a zone valve, connecting the remaining one lead of each of the thermostat and the zone valve between the first two of the four internal conductors, and connecting an end switch of the zone valve between the second two of the four internal conductors.

A more complete appreciation of the present invention and its scope may be obtained from the accompanying drawings, which are briefly summarized below, from the following detailed description of a presently preferred embodiment of the invention, and from the appended claims.

### BRIEF DESCRIPTION OF THE DRAWINGS

FIG. 1 is a broken perspective view of an integrated wiring assembly embodying the present invention connected to the components of a boiler heating system shown in schematic, perspective and block diagram form.

FIG. 2 is a perspective view of the integrated wiring assembly shown in FIG. 1.

FIG. 3 is a broken perspective view of one end connection section and one zone connection section of the integrated wiring assembly shown in FIGS. 1 and 2.

FIG. 4 is a cross-sectional view of the zone connection section of the integrated wiring assembly shown in FIG. 3, taken substantially in the plane of line 4-4.

FIG. 5 is a cross-sectional view of the zone connection section of the integrated wiring assembly shown in FIG. 3, taken substantially in the plane of line 5-5.

FIG. 6 is a schematic circuit connection diagram of the electrical connections of the boiler components at the end and zone connection sections established by the integrated wiring assembly shown in FIG. 1.

### DETAILED DESCRIPTION

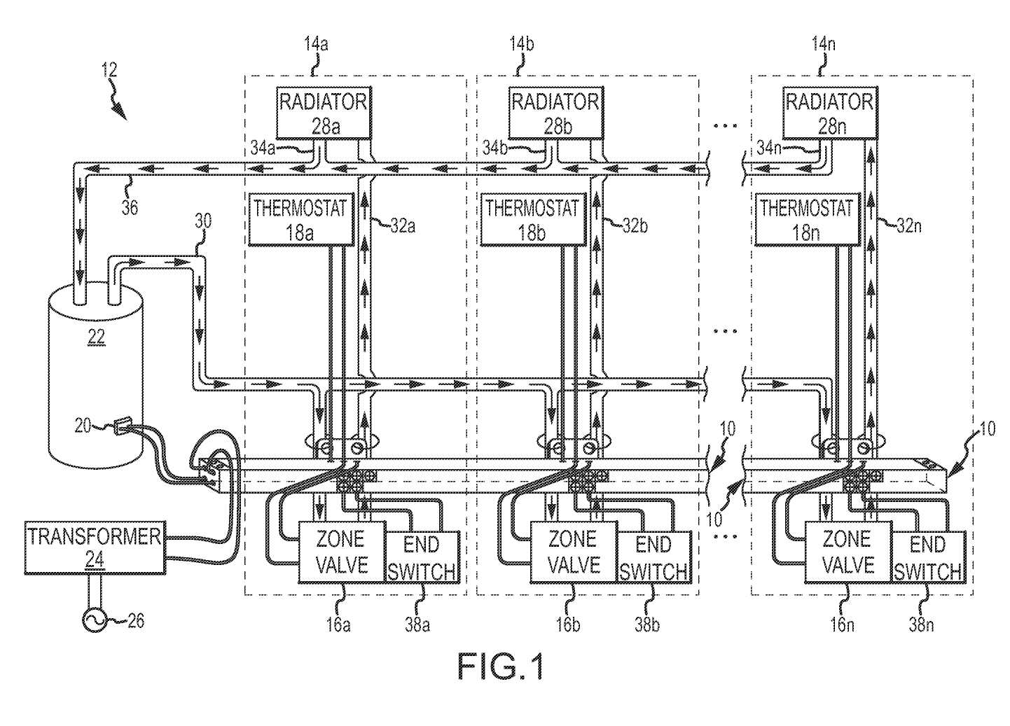

An integrated wiring assembly 10 which embodies the present invention is shown in FIG. 1. The integrated wiring assembly 10 electrically connects various components of a boiler heating system 12 within a plurality of different zones 14a-14n of a residential or commercial building (not shown). The boiler components of the heating system 12 include zone valves 16a-16n and thermostats 18a-18n, one of each of which is associated with each zone 14a-14n, and a start switch 20 of a boiler 22 and a transformer 24. The integrated wiring assembly 10 connects these components within each of the zones 14a-14n and in the boiler system 12 as a whole. The transformer 24 supplies electrical power from commercially available electrical power 26 to the integrated wiring assembly 10. The integrated wiring assembly 10 distributes the electrical power to the zone valves 16a-16n and thermostats 18a-18n to cause those components to function independently with respect to each zone 14a-14n, respectively, and to operate the boiler 22 with the start switch 20, all in a precise, easy-to-understand and organized manner.

At least one radiator 28a-28n is present in each of the zones 14a-14n, respectively. The radiators 28a-28n heat the zones 14a-14n. The boiler 22 heats the water which is supplied to a hot water supply manifold 30 to each of the zone valves 16a-16n. The zone valves 16a-16n open and close to control the supply of hot water to the radiators 28a-28n through hot water supply pipes 32a-32n. The thermostats 18a-18n control the opening and closing of the zone valves 16a-16n. Heat is extracted from the hot water in the radiators 28a-28n to heat the air within the zones 14a-14n. The relatively cooler water leaving the radiators 28a-28n flows back to the boiler 22 through cold water return pipes 34a-34n which connect to a cold water return manifold 36.

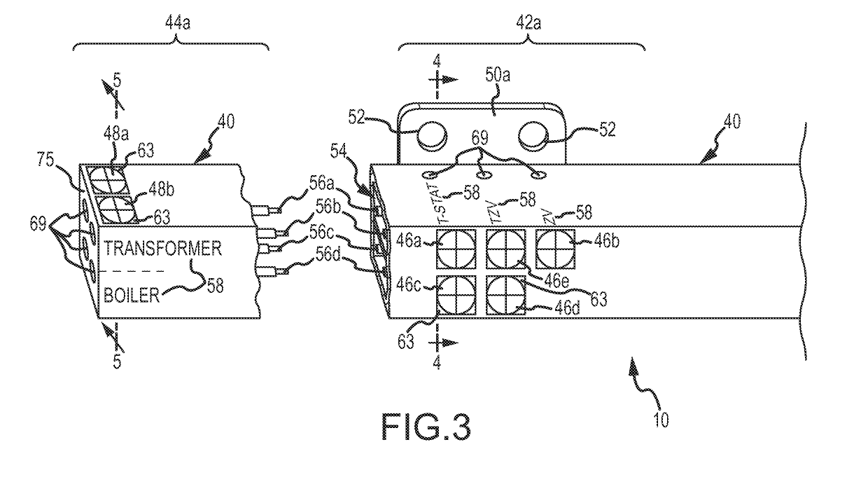

Electrical power is supplied from the transformer 24 to each of the thermostats 18a-18n by two internal conductors 56a and 56b (FIGS. 3, 4 and 6) of the integrated wiring assembly 10. When the temperature responsive switch of each thermostat 18a-18n closes, electrical power is supplied from the thermostat to open the zone valves 16a-16n to which each thermostat is connected. Each zone valve 16a-16n includes an end switch 38a-38n, respectively. The end switches 38a-38n are electrically connected in parallel to the boiler start switch 20 by two other internal conductors 56c and 56d (FIGS. 3, 4 and 6) of the integrated wiring assembly 10. When the thermostat 18a-18n opens a zone valve 16a-16n, the end switch 38a-38n associated with the open zone valve closes to activate the boiler start switch 20. The activated boiler start switch 20 causes the boiler 22 to commence heating water and causes a circulation pump (not shown) to start circulating the hot water through the open zone valve to the radiator and heat the air within the zone. If the boiler 22 includes a hot water storage tank (not shown) the activated boiler start switch 20 causes the circulation pump (not shown) to start circulating the hot water from the storage tank through the open zone valve to the radiator and heat the air within the zone. In the latter circumstance, the boiler 22 commences heating water in the storage tank when the temperature of the water in the storage tank drops below a desired level.

The integrated wiring assembly 10 facilitates creating the aforementioned electrical connections and thereby establishes the functionality between the various components of the boiler heating system 12. The manner in which the integrated wiring assembly accomplishes these functions is explained in connection with the details of the integrated wiring assembly 10 described below.

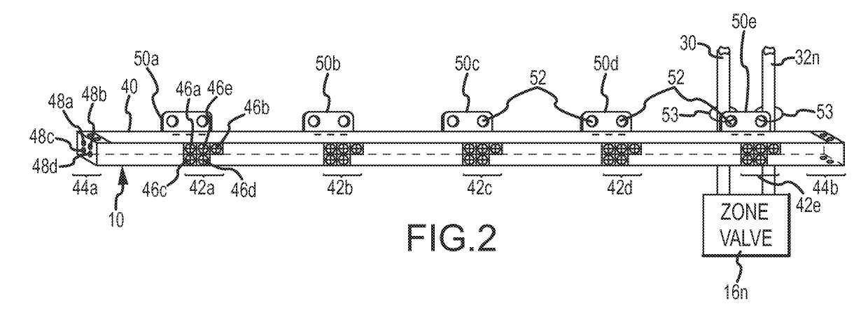

The integrated wiring assembly 10, shown in FIG. 2, is formed as an elongated housing 40 which is preferably made of plastic or other non-electrically conducting material. The integrated wiring assembly 10 is generally divided along its length into multiple (five are shown) intermediate zone connection sections 42a-42e located in the middle of the elongated housing 40, and two end connection sections 44a and 44b located at opposite ends of the elongated housing 40. The integrated wiring assembly 10 may include more or less than the five zone connection sections 42a-42e shown in FIG. 2, depending upon the length of the housing 40 and the number of zones to be connected.

Each of the zone connection sections 42a-42e includes five component zone connection terminals 46a-46e, as shown in FIGS. 2 and 3. Each of the zone connection terminals 46a-46e electrically connects to electrical conductors extending from the thermostat, the zone valve and the end switch associated with each zone. The two end connection sections 44a and 44b each include four end connection terminals 48a-48d. Only the end connection terminals 48a-48d of one end section, such as end section 44a, is needed to connect the integrated wiring assembly 10 to the transformer 24 and to the boiler start switch 20. The end connection terminals 48a-48d of the other end connection section, end connection section 44b for example, can be wired to the end connection terminals 48a-48d of an end connection section, such as end connection section 44a, of a second integrated wiring assembly 10. Proceeding in this manner, multiple integrated wiring assemblies 10 can be daisy chain connected together to accommodate a boiler heating system having more zones than a single integrated wiring assembly 10 can accommodate. Conversely, if only a single integrated wiring assembly 10 is required for a particular boiler heating system, that single integrated wiring assembly 10 need only include one end connection section 44a or 44b in order to connect to the transformer and boiler start switch.

Mounting tabs 50a-50e are formed onto the housing 40 of the integrated wiring assembly and facilitate hanging or mounting the integrated housing 10 on the hot water supply manifold 30 and the hot water supply pipes 32a-32n, as shown in FIG. 2. Each of the mounting tabs 50a-50e defines openings 52 through which a retaining tie or strap 53 is extended around the supply manifold 30 and the hot water supply pipe 32n (FIG. 2) to hold the integrated housing in a desired position at a height that makes working with the integrated housing 10 convenient.

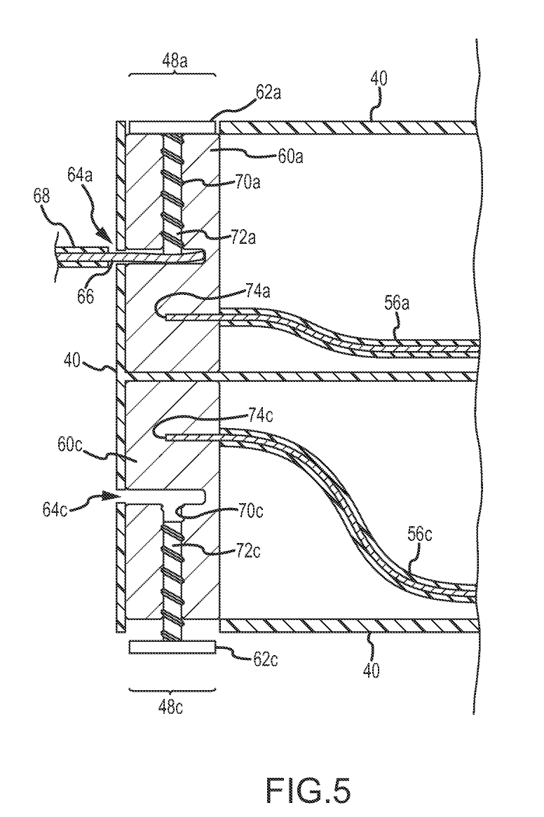

The housing 40 defines an interior space 54 in which four internal conductors 56a-56d are located, as shown in FIG. 3. The internal conductors 56a-56d extend from and electrically connect the end connection terminals 48a-48d of the end connection section 44a (FIGS. 2 and 5) to the corresponding end connection terminals 48a-48d of the end connection section 44b (FIGS. 2 and 5). The internal conductors 56a-56d are also electrically connected to the zone connection terminals 46a-46d of each zone connection section 42a-42e. Specifically, the internal conductor 56a electrically connects the end connection terminals 48a of both end connection sections 44a and 44b to the zone connection terminals 46a of the intermediate zone connection sections 42a-42e, the internal conductor 56b electrically connects the end connection terminals 48b of both end connection sections 44a and 44b to the zone connection terminals 46b of the zone connection sections 42a-42e, and so on. Indicia 58 which identifies the boiler component leads which attach to the particular zone and end connection terminals 46a-46e and 48a-48d are printed, embossed or otherwise attached to the housing 40 adjacent to each of the connection terminals, to thereby facilitate connecting the correct conductors to the terminals.

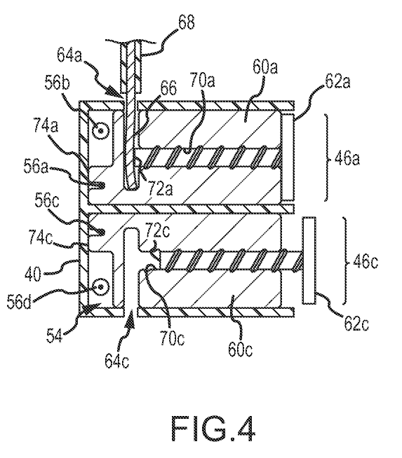

Two zone connection terminals 46a and 46c, which are representative of all of the zone connection terminals 46a-46e of each of the zone connection sections 42a-42e, are shown in detail in FIG. 4. Each of the zone connection terminals 46a and 46c includes an electrically conductive terminal body 60a and 60c which is located and retained within the interior space 54 of the housing 40. Terminal set screws 62a and 62c extend from of the terminal bodies 60a and 60c, respectively, and extend through access openings 63 formed in the housing 40. The terminal bodies 60a and 60c each define a clamping cavity 64a and 64c, respectively, which receives at least one exposed end 66 of a wire lead 68 or other conductor extending from the components of the boiler heating system 12 which are to be connected by use of the integrated wiring assembly 10. The end 66 of a wire lead 68 is inserted into the clamping cavity 64a of the terminal body 60a through an access hole 69 formed through the housing 40 in a position which aligns with each clamping cavity 64a and 64c.

Each of the terminal bodies 60a and 60c also defines threaded passageways 70a and 70c which receive the terminal screws 62a and 62c. Rotation of the set screws 62a and 62c causes them to move in or out of the threaded passageways 70a and 70c. The clamping cavities 64a and 64c intersect the threaded passageways 70a and 70c in the terminal bodies 60a and 60b, and allow the ends 72a and 72c of the terminal screws 62a and 62c to enter the clamping cavities 64a and 64c, respectively, when the set screws 62a and 62c are fully inserted into the threaded passageways 70a and 70c. Fully inserting the set screws 62a and 62c causes the ends 72a and 72c to clamp the exposed ends 66 of the wire leads 68 within the clamping cavities 64a and 64c, as shown by the end 72a of the terminal screw 62a clamping the exposed end 66 of wire lead 68. Clamping the exposed end of a wire lead within the clamping cavities 64a or 64c creates an electrical connection between those wire leads and the respective zone connection terminals 46a or 46c and also creates a mechanical connection to retain those wire leads in position.

The internal conductors 56a and 56c within the housing 40 are also electrically connected to the terminal bodies 60a and 60c, respectively. The internal conductors 56a and 56c are electrically connected to the terminal bodies 60a and 60c through conventional splicing mechanisms 74a and 74c which penetrate through exterior electrical insulation to reach the internal leads of the conductors 56a and 56c. The Internal conductors 56a, 56b, 56c and 56d (FIG. 2) are connected to only one of the terminal bodies at each of the intermediate zone connection sections. As shown in FIG. 4, the internal conductors 56b and 56d are not electrically connected to the terminal bodies 60a or 60c, but instead are connected to the terminal bodies corresponding to the zone connection terminals 46b and 46d.

The zone connection terminal 46e does not connect to any of the internal conductors 56a-56d. Instead, the zone connection terminal 46e serves as a junction terminal for connecting a wire lead from the thermostat in series with a wire lead from the zone valve in each zone, as is shown in FIG. 1. To make the junction connection, the exposed ends of the two lead wires from the thermostat in the zone valve are inserted into the single clamping cavity and the terminal set screw is tightened to make the electrical series connection at the zone connection terminal 46e.

Two end connection terminals 48a and 48c, which are representative of all of the end connection terminals 48a-48d of both end connection sections 44a and 44b, are shown in detail in FIG. 5. The structural details and operation of each end connection terminal is similar to that of the zone connection terminals 46a-46e (FIG. 4) previously described. For that reason, the two end connection terminals 48a and 48c utilize the same electrically conductive terminal bodies 60a and 60c, terminal set screws 62a and 62c, access openings 63, clamping cavities 64a and 64c, access holes 69, threaded passageways 70a and 70b, set screw ends 72a and 72b and splicing mechanisms 74a and 74b. The access hole 69 for the end connection terminals 48a-48d are formed in an end 75 attached to the end of the housing 40, rather than in the housing 40 itself which is the case for the access holes 69 for the zone connection terminals 46a-46e.

The end connection terminals 48a-48d at one end connection section, for example end connection section 44a connects to the wire leads or conductors from the boiler start switch 20 and the transformer 24. Consequently, the wire leads 68 shown in FIG. 5 extend from either the start switch 20 or the transformer 24. Also, the internal conductors 56a-56d within the housing 40 begin and end with the connections to the terminal bodies of the end connection terminals 48a-48d, respectively. Conventional splicing mechanisms 74a and 74c make those connections to the ends of the conductors 56a-56d.

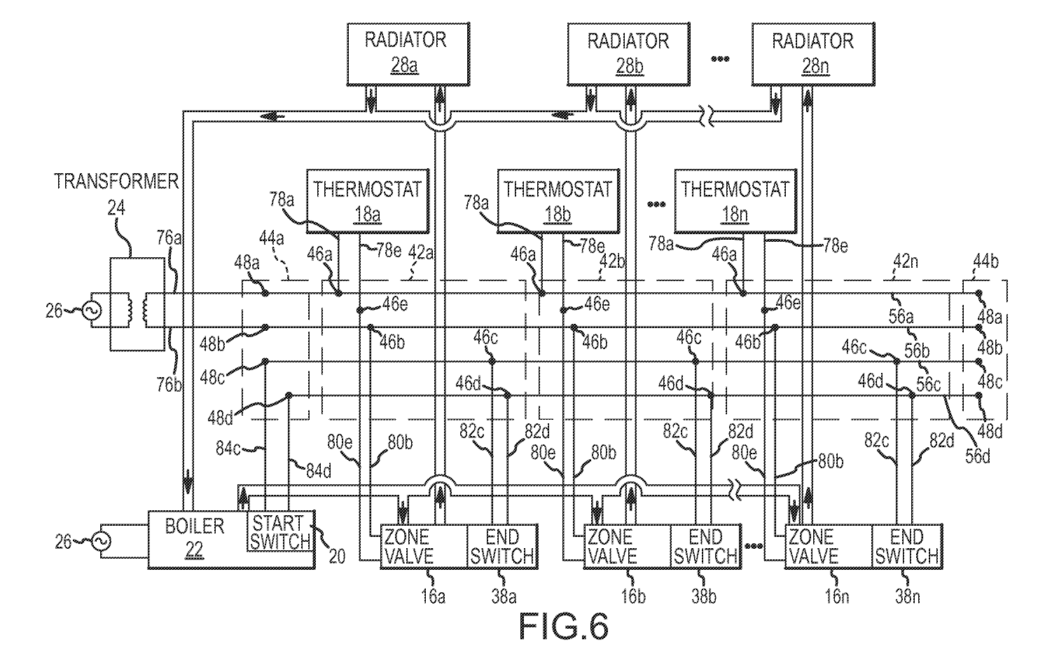

The internal connections of the integrated wiring assembly 10 to the thermostat, zone valves, and end switches is shown in FIG. 6. The transformer 24 is connected to end connection terminals 48a and 48b of end connection section 44a by transformer leads 76a and 76b. The transformer 24 supplies a voltage potential across the transformer leads 76a and 76b which is conducted by the internal conductors 56a and 56b. Each of the thermostats 18a-18n is connected to the zone connection terminals 46a and 46e via thermostat leads 78a and 78e. Each of the zone valves 16a-16n is connected to the zone connection terminals 46b and 46e via zone valve leads 80b and 80e. The zone connection terminals 46e electrically connect the leads 78e from each of the thermostats 18a-18n to the leads 80e from each of the corresponding zone valves 16a-16n in each zone.

The end switches 38a-38n are electrically connected to the zone connection terminals 46c and 46d via end switch leads 82c and 82d. The boiler start switch 20 is connected to the end connection terminals 48c and 48d of end connection section 44a by start switch leads 84c and 84d. Each of the end switches 38a-38n is open when the corresponding one of the zone valves 16a-16n is closed. Likewise, each of the end switches 38a-38n is closed when the corresponding one of the zone valves 16a-16n is opened. Thus, when any one of the zone valves 16a-16n is open, an electrical connection is created between the internal conductors 56c and 56d through the end switch corresponding to that zone valve. The electrical connection between the internal conductors 56c and 56d when an end switch is closed completes a circuit through the start switch leads 84c and 84d and starts the boiler 22 and/or its circulation pump.

As an example of operation, the interaction between the various components of the boiler heating system 12 to heat the air within the exemplary zone 14a is next described. Similar operation exists with respect to the other zones 14b-14n. The thermostat 18a is preset to a preselected temperature. When the temperature of the air within the zone 14a falls beneath that preselected temperature, the internal temperature responsive switch within the thermostat 18a closes. Closing the temperature responsive switch causes the voltage potential across the internal conductors 56a and 56b to be conducted to the zone valve 16a which causes the zone valve 16a to open. As a result of the zone valve 16a opening, the end switch 38a closes. The closing of the end switch 38a causes an electrical connection between the internal conductors 56c and 56d, which starts the boiler 22 and/or its circulation pump. The starting of the boiler 22 causes water within the boiler 22 to be heated and also causes the circulation pump to pump the heated water to the hot water supply manifold 30. The heated water flows from the hot water supply manifold 30, through the open zone valve 16a and through the hot water supply pipe 32a to the radiator 28a. Heat is extracted from the heated water flowing through the radiator 28a thereby heating the air and cooling the water. The relatively cooler water from the radiator 28a flows back to the boiler 22 through the cold water return pipe 34a and the cold water return manifold 36.

As more and more heated water flows through the radiator 28a, the air within the zone 14a gets warmer and warmer until the temperature of the air within the zone 14a reaches the preselected temperature of the thermostat 18a. When the temperature of the air within the zone 14a reaches that preselected temperature, the temperature responsive switch of the thermostat 18a opens. Opening the temperature responsive switch of the thermostat 18a causes the zone valve 16a to close, which causes the end switch 38a to open, which in turn causes the start switch 20 to open and the boiler 22 to turn off, provided that none of the other end switches 38b-38n are still closed. In this manner, the boiler heating system 12 independently heats the various zones 14a-14n within the building.

The integrated wiring assembly 10 can substantially reduce the amount of time taken by a technician to wire the components of a boiler heating system. The integrated wiring assembly 10 removes the guess-work and confusion often involved when a technician attempts to wire components of a boiler heating system. Time spent training technicians to be proficient at installing and servicing problems with boiler heating systems is a significant cost. Significantly less training time is required for new technicians when they are trained to wire the components of a boiler heating system using the integrated wire housing 10. Use of the integrated wiring assembly 10 to connect the components of a boiler heating system also reduces the risk that a boiler heating system component will be damaged as a result of incorrectly connecting the component to the boiler heating system. The use of the integrated wiring assembly 10 results in a central location at which the electrical components of the boiler heating system are neatly wired. The neat and orderly wiring facilitates speedy problem determination and resolution concerning the boiler heating system. Many other advantages and improvements will become apparent upon fully comprehending the scope and significance of the present invention.

A presently preferred embodiment of the present invention and many of its improvements have been described with a degree of particularity. This description is a preferred example of implementing the invention, and is not necessarily intended to limit the scope of the invention. The scope of the invention is defined by the following claims.

What is claimed:

1. An integrated wiring assembly for use in a multi-zone boiler heating system to electrically connect a thermostat and a zone valve associated with each of a plurality of zones, and to electrically connect a start switch and an end switch associated with each zone valve, and to electrically connect to a transformer of the boiler heating system; the integrated wiring assembly comprising:
a housing which defines an interior space;
an end connection section connected to the housing and operative for connecting to the start switch and the transformer, the end connection section including first, second, third and fourth end connection terminals;
a plurality of zone connection sections connected to the housing and operative for connecting to the thermostat, the zone valve and the end switch of the zone valve at each zone, each zone connection section including first, second, third, fourth and fifth zone connection terminals;
first, second, third and fourth internal electrical conductors within the interior space of the housing, the first internal conductor commonly connecting the first zone connection terminals of each zone connection section and the first end connection terminal of the end connection section, the second internal conductor commonly connecting the second zone connection terminals of each zone connection section and the second end connection terminal of the end connection section, the third internal conductor commonly connecting the third zone connection terminals of each zone connection section and the third end connection terminal of the end connection section, and the fourth internal conductor commonly connecting the fourth zone connection terminals of each zone connection section and the fourth end connection terminal of the end connection section; and wherein:
the first and second end connection terminals are for connecting to two lead conductors of the transformer;
the third and fourth end connection terminals are for connecting to two lead conductors of the start switch;
the first zone connection terminal of each zone connection section is for connecting to one lead conductor from the thermostat in the zone associated with the zone connection section;
the fifth zone connection terminal of each zone connection section is for connecting to another lead conductor from the thermostat in the zone and to one lead from the zone valve in the zone associated with the zone connection section;
the second zone connection terminal of each zone connection section is for connecting to another lead from the zone valve in the zone associated with the zone connection section;
the third zone connection terminal of each zone connection section is for connecting to one lead from the end switch of the zone valve in the zone associated with the zone connection section; and
the fourth zone connection terminal of each zone connection section is for connecting to the other lead from the end switch of the zone valve in the zone associated with the zone connection section.

2. An integrated wiring assembly as defined in claim 1, further comprising:
indicia attached to the housing adjacent to the end connection terminals and the zone connection terminals which identifies the lead conductor to be attached to each of the zone and end connection terminals.

3. An integrated wiring assembly as defined in claim 1, wherein:
the housing is elongated;
the end connection section is located at one end of the elongated housing; and
each zone connection section is located between the end connection section and the other opposite end of the elongated housing.

4. An integrated wiring assembly as defined in claim 3, further comprising:
a plurality of mounting structures attached to the housing by which to mount the integrated wiring assembly to a support.

5. An integrated wiring assembly as defined in claim 3, further comprising:
another aforesaid end connection section located at the opposite end of the elongated housing; and wherein:
the first, second, third and fourth end connection terminals of the other end connection section connected to the first, second, third and fourth internal conductors, respectively.

6. An integrated wiring assembly as defined in claim 1, wherein:
each of the end and zone connection terminals comprises a terminal body, a clamping member attached to the terminal body by which to connect the lead conductor to the terminal body, and a mechanism which connects the terminal body to an internal conductor.

7. A multi-zone boiler heating system using an integrated wiring assembly as defined in claim 1, comprising:
a boiler for heating heat transfer liquid, the boiler including the start switch;
a plurality of radiators, at least one radiator located in each zone;
a plurality of heat transfer liquid conducting pipes which connect the boiler to all of the zone valves and each zone valve to the radiator of its associated zone and each radiator to the boiler in a fluid circulatory path; and wherein:
the end connection terminals are connected to the lead conductors of the start switch and the transformer; and
the zone connection terminals are connected to the lead conductors of the thermostats, the zone valves and the end switches.

8. A method of using an integrated wiring assembly as defined in claim 1 to electrically connect the thermostat and the zone valve in each of zones, and to electrically connect the start switch and the end switch associated with each zone valve, and to electrically connect to a transformer; the method comprising:
connecting the first and second end connection terminals to two lead conductors of the transformer;
connecting the third and fourth end connection terminals to two lead conductors of the start switch;
connecting the first zone connection terminal of each zone connection section to one lead conductor from the thermostat in the zone associated with the zone connection section;
connecting the fifth zone connection terminal of each zone connection section to another lead conductor from the thermostat in the zone and to one lead from the zone valve in the zone associated with the zone connection section;
connecting the second zone connection terminal of each zone connection section to another lead from the zone valve in the zone associated with the zone connection section;
connecting the third zone connection terminal of each zone connection section to one lead from the end switch of the zone valve in the zone associated with the zone connection section; and
connecting the fourth zone connection terminal of each zone connection section to the other lead from the end switch of the zone valve in the zone associated with the zone connection section.

9. An integrated wiring assembly for use in a multi-zone boiler heating system to electrically connect components of the boiler heating system, comprising:
a housing which defines an interior space;
an end connection section comprising four end connection terminals, each end connection terminal mounted within the housing and adapted for electrically connecting to a wire further connected to one of the boiler heating system components;
a plurality of zone connection sections, each zone connection section comprising five zone connection terminals, each zone connection terminal mounted within the housing and adapted for electrically connecting to a wire further connected to one of the boiler heating system components;
four internal conductors positioned within the interior space, each of the internal conductors electrically connected to one of the four end connection terminals, each of the internal conductors further electrically connected to one of the four zone connection terminals of each zone connection section; and
wherein one of the five zone connection terminals of each zone connection section is not electrically connected to any other connection terminals.

10. An integrated wiring assembly as defined in claim 9, wherein the aforementioned end connection section is a first end connection section, the integrated wiring assembly further comprising:
a second end connection section, the second end connection section comprising four end connection terminals, each end connection terminal mounted within the housing and electrically connected to a different one of the four internal conductors.

11. An integrated wiring assembly as defined in claim 10, further comprising:
indicia attached to the housing adjacent to the end connection terminals and the zone connection terminals which identifies which of the components of the boiler heating system are for connecting to the end and zone connection terminals.
